(19) United States
(12) Patent Application Publication
(10) Pub. No.: US 2006/0068549 A1
(43) Pub. Date: Mar. 30, 2006

(54) Image display device

(76) Inventors: Shigeo Takenaka, Fukaya-shi (JP); Satoshi Ishikawa, Fukaya-shi (JP); Masaru Nikaido, Ibo-gun (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/271,855

(22) Filed: Nov. 14, 2005

Related U.S. Application Data
(63) Continuation of application No. PCT/JP04/07054, filed on May 18, 2004.

(30) Foreign Application Priority Data
May 20, 2003 (JP) 2003-141990

(51) Int. Cl. H01L 21/336

(52) U.S. Cl. 438/261

(57) ABSTRACT

An image display device includes a first substrate having a phosphor screen, and a second substrate opposed to the first substrate across a gap and having a plurality of electron emission sources which excite the phosphor screen. A spacer assembly which supports atmospheric load acting on the first and second substrates is arranged between the first and second substrates. The spacer assembly has a plate-shaped spacer support member which is arranged between the first and second substrates and has a plurality of electron beam apertures opposed to the electron emission sources, individually, and a plurality of spacers set up only on the second substrate side of the spacer support member and individually abutting against the second substrate.

### CROSS REFERENCE TO RELATED APPLICATIONS

This is a Continuation Application of PCT Application No. PCT/JP2004/007054, filed May 18, 2004, which was published under PCT Article 21(2) in Japanese.

This application is based upon and claims the benefit of priority from prior Japanese Patent Application No. 2003-141990, filed May 20, 2003, the entire contents of which are incorporated herein by reference.

### BACKGROUND OF THE INVENTION

1. Field of the Invention

This invention relates to an image display device provided with substrates opposed to each other and spacers located between the substrates.

2. Description of the Related Art

In recent years, various flat image display devices have been noticed as a next generation of lightweight, thin display devices to replace cathode-ray tubes (CRTs). A surface-conduction electron emission device (SED) has been developed as a kind of a field emission device (FED) that serves as a flat display device.

This SED comprises a first substrate and a second substrate that are opposed to each other across a predetermined gap. These substrates have their respective peripheral portions joined together by a rectangular sidewall, thereby constituting a vacuum envelope. Three-color phosphor layers and a metal back are formed on the inner surface of the first substrate. Arranged on the inner surface of the second substrate are a large number of electron emitting elements for use as electron sources, which correspond to pixels, individually, and excite the phosphors. Each electron emitting element is formed of an electron emitting portion, a pair of electrodes that apply voltage to the electron emitting portion, etc.

For the SED described above, it is important to maintain a high degree of vacuum in a space between the first substrate and the second substrate, that is, in the vacuum envelope. If the degree of vacuum is low, the life of the electron emitting elements, and hence, the life of the device shorten inevitably. Since a vacuum is maintained between the first substrate and the second substrate, moreover, atmospheric pressure acts on the first substrate and the second substrate. In order to support the atmospheric load that acts on these substrates and maintain the gap between the substrates, therefore, a large number of plate-shaped or columnar spacers are located between the two substrates.

In order to locate the spacers to cover the first substrate and the second substrate entirely, spacers in the form of very thin plates or very slender columns should be used lest they touch the phosphors on the first substrate and the electron emitting elements on the second substrate. Since these spacers must inevitably be set very close to the electron emitting elements, an insulating material must be used for the spacers. At the same time, more spacers are needed in order to make the first substrate and the second substrate thinner.

For the alignment of the spacers with the phosphors on the first substrate and between the electron emitting elements on the second substrate, a method is proposed in which the spacers are mounted directly between the phosphors or between the electron emitting elements. Proposed in Jpn. Pat. Appln. KOKAI Publication No. 2001-272927, moreover, is a method in which a large number of spacers are formed with high positional accuracy on the obverse and reverse sides of a metal plate that is previously formed with apertures through which electrons pass and the spacers formed on the metal plate are aligned with a first substrate or a second substrate.

In the SED provided with the spacers constructed in this manner, one end of each spacer abuts against the inner surface of the first substrate through the metal back and the phosphor screen. Since these spacers are formed having the shape of very thin plates or very slender columns, however, the spacer ends may possibly damage the metal back or the phosphor screen in positions where they abut against the first substrate. Further, there is a possibility of the metal back on the inner surface of the first substrate partially peeling off. A peeled part of the metal back becomes unwanted matter in the SED, which may possibly cause electric discharge.

### BRIEF SUMMARY OF THE INVENTION

This invention has been made in consideration of these circumstances, and its object is to provide an image display device, capable of preventing spacers from damaging a metal back or a phosphor screen and improved in withstand voltage property to resist electric discharge.

In order to achieve the object, an image display device according to an aspect of the invention comprises: a first substrate having a phosphor screen; a second substrate opposed to the first substrate across a gap and having a plurality of electron emission sources which excite the phosphor screen; and a spacer assembly which supports atmospheric load acting on the first and second substrates,
the spacer assembly having a plate-shaped spacer support member which is arranged between the first and second substrates with being in contact with the first substrate and opposed to the first substrate and the second substrate and has a plurality of electron beam apertures opposed to the electron emission sources, individually, and a plurality of spacers set up on the second substrate side of the spacer support member and individually abutting against the second substrate.

According to the image display device constructed in this manner, the spacers are provided only on the second substrate side of the spacer support member, so that the length of each spacer can be increased, and the distance between the spacer support member and the second substrate can be lengthened. Thus, the withstand voltage property between the spacer support member and the second substrate is improved, so that generation of electric discharge between them can be restrained.

If the spacer support member is provided in contact with the inner surface of the first substrate, moreover, the spacer support member comes into planar contact with the metal back on the inner surface of the first substrate, thereby pressing the metal back and the phosphor screen in a planar fashion. Accordingly, exfoliation of the metal back and damage to the metal back and the phosphor screen can be prevented. Thus, a good image quality level can be maintained for a long time. At the same time, generation of electric discharge attributable to exfoliation of the metal back can be restrained.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing an SED according to an embodiment of this invention;

FIG. 2 is a perspective view of the SED cut along line II-II of FIG. 1;

FIG. 3 is a sectional view enlargedly showing the SED; and

FIG. 4 is a plan view showing a spacer assembly of the SED.

### DETAILED DESCRIPTION OF THE INVENTION

An embodiment in which this invention is applied to an SED will now be described in detail with reference to the drawings.

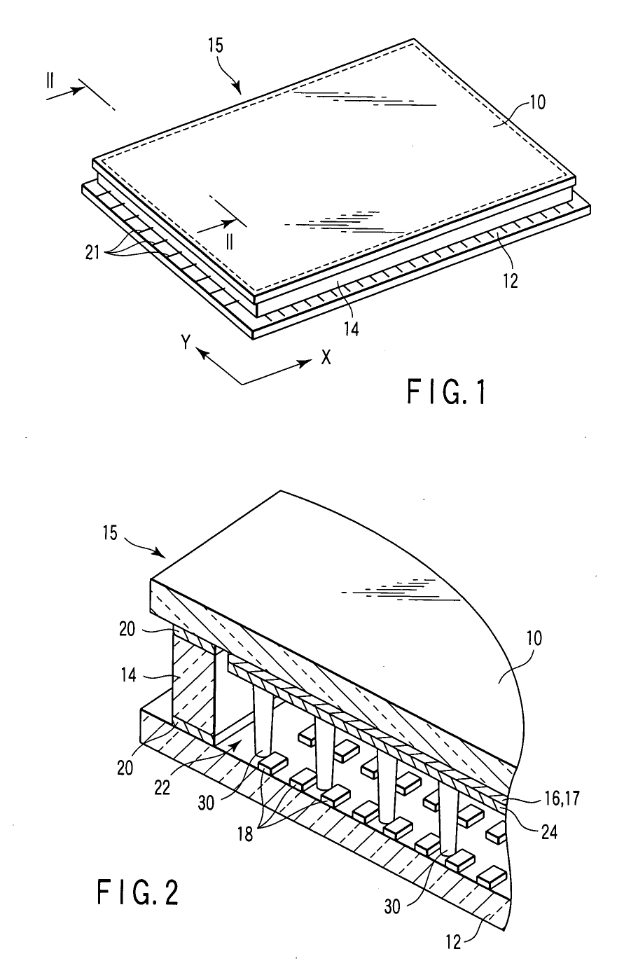

As shown in FIGS. 1 to 3, the SED comprises a first substrate 10 and a second substrate 12, which are each formed of a rectangular glass plate. These substrates are opposed to each other with a gap of about 1.0 to 2.0 mm between them. The first substrate 10 and the second substrate 12 have their respective peripheral edge portions joined together by a glass sidewall 14 in the shape of a rectangular frame. They constitute a flat rectangular vacuum envelope 15 that is internally kept at high vacuum.

A phosphor screen 16 is formed as a phosphor surface on the entire inner surface of the first substrate 10. The phosphor screen 16 is formed by arranging phosphor layers R, G and B, which glow red, blue, and green when hit by electrons, and a light shielding layer 11 side by side. The phosphor layers R, G and B are formed in stripes or dots. A metal back 17 of aluminum or the like and a getter film (not shown) are successively formed on the phosphor screen 16.

Located on the inner surface of the second substrate 12 are a large number of surface-conduction electron emitting elements 18 that individually emit electron beams as electron emission sources for exciting the phosphor layers of the phosphor screen 16. These electron emitting elements 18 are arranged in a plurality of columns and a plurality of rows corresponding to one another for each pixel. Each electron emitting element 18 is formed of an electron emitting portion (not shown) and a pair of element electrodes or the like that apply voltage to the electron emitting portion. A large number of wires 21 that supply potential to the electron emitting elements 18 are provided in a matrix on the inner surface of the second substrate 12, and their end portions are drawn out to the peripheral edge portions of the vacuum envelope 15.

The sidewall 14 that serves as a joint member is sealed to the respective peripheral edge portions of the first substrate 10 and the second substrate 12 with a sealing material 20, such as low-temperature melting glass or low-temperature melting metal, and joins the first substrate and the second substrate together.

As shown in FIGS. 2 and 4, the SED comprises a spacer assembly 22 located between the first substrate 10 and the second substrate 12. In the present embodiment, the spacer assembly 22 comprises a spacer support member 24 formed of a rectangular metal plate and a number of columnar spacers set up integrally only on one of the surfaces of the spacer support member.

Specifically, the spacer support member 24 has a first surface 24a opposed to the inner surface of the first substrate 10 and a second surface 24b opposed to the inner surface of the second substrate 12, and is located parallel to these substrates. A large number of electron beam apertures 26 are formed in the spacer support member 24 by etching or the like. The electron beam apertures 26 are arranged opposite to the electron emitting elements 18, individually, and electron beams emitted from the electron emitting elements are passed through them.

The spacer support member 24 is formed of, for example, an iron-nickel-based metal plate with a thickness of 0.1 to 0.25 mm, and each electron beam aperture 26 is in the form of a rectangle measuring 0.15 to 0.25 mm by 0.15 to 0.25 mm, for example. Formed on the surface of the spacer support member 24 is a fired high-resistance film 40 as an insulating layer coated with an insulating material that consists mainly of glass, ceramic, etc. According to the present embodiment, the first and second surfaces 24a and 24b of the spacer support member 24 and the inner wall surface of each electron beam aperture 26 are covered by the high-resistance film 40 of Li-based borosilicate alkali glass with a thickness of about 10 μm. The spacer support member 24 is provided in a manner such that its first surface 24a is in planar contact with the inner surface of the first substrate 10 with the getter film, metal back 17, and phosphor screen 16 between them.

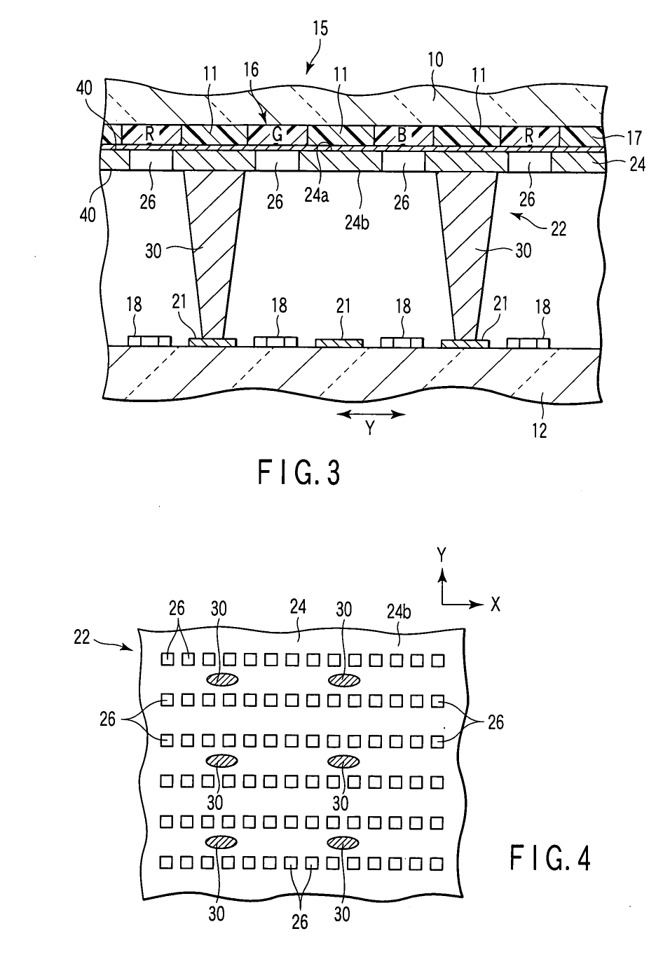

If the longitudinal and transverse directions of the first substrate 10 and the second substrate 12 are X and Y, respectively, as shown in FIGS. 3 and 4, the electron beam apertures 26 in the spacer support member 24 are arranged at given pitches in the X-direction. In the Y-direction, they are arranged at pitches larger than those in the X-direction. The phosphor layers R, G and B of the phosphor screen 16 formed on the first substrate 10 are arranged at the same pitches as the electron beam apertures 26 in the X-direction and the Y-direction, and face the electron beam apertures, individually. Likewise, the electron emitting elements 18 on the second substrate 12 are arranged at the same pitches as the electron beam apertures 26 in the X-direction and the Y-direction, and face the electron beam apertures, individually. Thus, the electron emitting elements 18 face their corresponding phosphor layers through the electron beam apertures 26.

As shown in FIGS. 2 to 4, spacers 30 are set up integrally on the second surface 24b of the spacer support member 24. Extended ends of the spacers 30 abut against the inner surface of the second substrate 12. Here the extended ends of the spacers 30 are situated on the wires 21 that are provided on the inner surface of the second substrate 12. Each of the spacers 30 has a tapered form, the diameter of which is reduced from the side of the spacer support member 24 toward its extended end. For example, the spacer 30 is formed having a height of about 1.4 mm. The cross section of the spacer 30 along a direction parallel to the surfaces of the spacer support member 24 is substantially elliptic.

The spacer assembly 22 constructed in this manner is located between the first substrate 10 and the second substrate 12. The spacer assembly 22 supports the atmospheric load that acts on these substrates, thereby keeping the space between the substrates at a given value, with the spacer support member 24 in planar contact with the first substrate 10 and with the respective extended ends of the spacers 30 abutting against the inner surface of the second substrate 12.

The SED comprises a voltage supply unit (not shown) that applies voltages to the spacer support member 24 and the metal back 17 of the first substrate 10. This voltage supply unit is connected to the spacer support member 24 and the metal back 17, and applies the same voltage to the spacer support member and the metal back or applies a voltage a little higher than a voltage for the metal back to the spacer support member, for example. In displaying an image on the SED, the electron beams emitted from the electron emitting elements 18 are accelerated by anode voltages that are applied to the phosphor screen 16 and the metal back 17, and are collided with the phosphor screen 16. Thus, the phosphor layers of the phosphor screen 16 are excited to luminescence, thereby displaying the image.

The following is a description of a manufacturing method for the SED constructed in this manner.

First, in manufacturing the spacer assembly 22, a metal plate of Fe-50% Ni with a plate thickness of 0.12 mm is degreased, cleaned, and dried. Subsequently, the electron beam apertures 26 are formed in this metal plate by etching, whereupon the spacer support member 24 is completed. Thereafter, the whole spacer support member 24 is oxidized by oxidation to form an insulating film on the spacer support member surface including the inner surfaces of the electron beam apertures 26. Further, the high-resistance film 40 is formed by coating the insulating film with a coating liquid, consisting mainly of glass, by spraying, and drying it at 90° C. for 15 minutes and then firing it at 550° C.

Subsequently, a molding die (not shown) in the form of a rectangular plate having substantially the same size as the spacer support member 24 is prepared. The molding die has a large number of through holes for spacer molding. The molding die is brought intimately into contact with the second surface 24b of the spacer support member 24 in a manner such that it is positioned so that the through holes face the spacer support member between the electron beam apertures 26. The molding die and the spacer support member 24 are fixed intimately in contact with each other by using a camper (not shown) or the like. A remover is applied to the molding die in advance.

Thereafter, a pasty spacer forming material is supplied to the molding die from its outer surface side, whereby the through holes of the molding die are filled with the spacer forming material. A glass paste that contains at least an ultraviolet-curing binder (organic component) and a glass filler is used as the spacer forming material. Subsequently, ultraviolet rays (UV) are applied to the filled spacer forming material from the outer surface side of the molding die, whereby the spacer forming material is UV-cured. Thereafter, the material may be thermally set as required. Then, the remover that is applied to the through holes of the molding die is thermally decomposed by heat treatment at 280° C., whereby a gap is formed between the spacer forming material and the die, and the molding die is released from the spacer support member 24.

Further, the spacer support member 24 filled with the spacer forming material is heat-treated in a heating oven to remove the binder from the spacer forming material, and thereafter, the spacer forming material is regularly fired at about 525° C. for 30 minutes to one hour. Thereupon, the spacer forming material is vitrified, and the spacer assembly 22 having the spacers 30 that are integral with the spacer support member 24 is obtained. Since the spacer firing temperature is not higher than the softening point temperature of the high-resistance film that is formed on the spacer support member 24, the spacers can be fired without degrading the film quality of the high-resistance film.

On the other hand, the first substrate 10, which is provided with the phosphor screen 16 and the metal back 17, and the second substrate 12, which is provided with the electron emitting elements 18 and the wires 21 and joined with the sidewall 14, are prepared in advance. Then, the spacer assembly 22 obtained in the aforesaid manner is positioned on the second substrate 12. In this state, the first substrate 10, second substrate 12, and spacer assembly 22 are located in a vacuum chamber, and the vacuum chamber is evacuated. Then, the first substrate is joined to the second substrate by the sidewall 14 with the first substrate 10, second substrate 12, and spacer assembly 22 aligned in given positions. Thus, the SED is manufactured having the spacer assembly 22.

According to the SED constructed in this manner, the spacers 30 are provided only on the side of the second substrate 12 of the spacer support member 24, so that the length of each spacer can be increased, and the distance between the spacer support member 24 and the second substrate 12 can be lengthened. Thus, the withstand voltage property between the spacer support member and the second substrate is improved, so that generation of electric discharge between them can be restrained.

The spacer support member 24 is provided in contact with the inner surface of the first substrate 10. Therefore, the spacer support member 24 comes into planar contact with the metal back 17 that is provided on the inner surface of the first substrate 10, thereby pressing the metal back and the phosphor screen 16 in a planar fashion. Accordingly, exfoliation of the metal back 17 and damage to the metal back and the phosphor screen can be prevented. Thus, a good image quality level can be maintained for a long time. At the same time, generation of electric discharge attributable to exfoliation of the metal back can be restrained, so that the obtained SED is improved in reliability.

The voltage that is applied to the spacer support member 24 is set to be equal to or a little lower than a voltage applied to the first substrate 10. Alternatively, this voltage may be set to be a little higher than the voltage applied to the first substrate 10. If the voltage applied to the spacer support member 24 is higher than the voltage applied to the first substrate 10 by 0.2 to 1 kV, for example, reflected electrons and secondary electrons generated from the first substrate can be absorbed by the spacer support member 24, so that the contrast of displayed images can be improved. If the same voltage is applied to the spacer support member 24 and the first substrate 10, the insulating layer provided on the side of the first surface 24a of the spacer support member may be omitted.

The present invention is not limited directly to the embodiment described above, and its components may be embodied in modified forms without departing from the scope or spirit of the invention. Further, various inventions may be made by suitably combining a plurality of components described in connection with the foregoing embodiments. For example, some of the components according to the foregoing embodiment may be omitted. Furthermore, components according to different embodiments may be combined as required.

In the embodiment described above, for example, the spacer support member is directly in contact with the inner surface of the first substrate. Alternatively, however, belt-shaped or plate-shaped interposed members having a contact area larger than that of the spacers may be interposed between the spacer support member and the first substrate. Also in this case, the interposed members can press the metal back in a planar fashion, thereby preventing exfoliation of the metal back and damage to the metal back and the phosphor screen.

In addition, the diameter and height of the spacers and the dimensions, materials, etc., of the other components are not limited to the foregoing embodiment, but may be suitably selected as required. The spacers are not limited to the columnar shape but may alternatively be plate-shaped. This invention is not limited to the device that uses surface-conduction electron emitting elements as electron sources, but is also applicable to image display devices that use electron sources of any other types, such as the field-emission type, carbon nanotubes, etc.

What is claimed is:

1. An image display device comprising:
a first substrate having a phosphor screen;
a second substrate opposed to the first substrate across a gap and having a plurality of electron emission sources which excite the phosphor screen; and
a spacer assembly which supports atmospheric load acting on the first and second substrates,
the spacer assembly having a plate-shaped spacer support member which is arranged between the first and second substrates with being in contact with the first substrate and opposed to the first substrate and the second substrate and has a plurality of electron beam apertures opposed to the electron emission sources, individually, and a plurality of spacers set up on the second substrate side of the spacer support member and individually abutting against the second substrate.

2. The image display device according to claim 1, wherein the spacer support member has a first surface in contact with the first substrate and a second surface opposed to the second substrate having the spacers set up thereon.

3. The image display device according to claim 1, wherein the first substrate has a metal back formed on the inner surface of the first substrate so as to overlap the phosphor screen, and the spacer support member is in contact with the metal back.

4. The image display device according to claim 1, wherein the spacer support member is formed of a metal plate.

5. The image display device according to claim 1, wherein at least one surface of the spacer support member is covered by an insulating layer.

6. The image display device according to claim 1, wherein each surface of the spacer support member is covered by an insulating layer.

7. The image display device according to claim 5, comprising a voltage supply unit which applies a voltage to the first substrate and a voltage not lower than the voltage applied to the first substrate to the spacer support member.
